(19) United States
(12) Patent Application Publication
(10) Pub. No.: US 2018/0136355 A1
(43) Pub. Date: May 17, 2018

(54) DIGITAL EXCITATION SIGNAL GENERATOR FOR DOWNHOLE LOGGING TOOLS

(71) Applicant: Halliburton Energy Services, Inc., Houston, TX (US)

(72) Inventors: Xiaohong ZHANG, Singapore (SG); Alberto QUINTERO, Houston, TX (US); Guosheng JIN, Singapore (SG); Joni LIE, Singapore (SG)

(21) Appl. No.: 15/301,890

(22) PCT Filed: Aug. 3, 2015
(86) PCT No.: PCT/US2015/043440

§ 371 Date: Oct. 4, 2016

(51) Int. Cl. G01V 3/24; H03K 17/0812; E21B 47/12; H03K 3/01

(52) U.S. Cl. CPC G01V 3/24; H03K 3/01; E21B 47/12; H03K 17/08122

(57) ABSTRACT

A digital excitation signal generator can be used to modulate excitation current or voltage to be injected into a subterranean formation by a downhole logging tool. The digital excitation signal generator can include a processor and a pulse-width modulator (“PWM”) device. The processor can generate a digital waveform and provide the digital waveform to the PWM device. The PWM device can convert the digital waveform into PWM pulses. The PWM device can be coupled to an interface. The interface can use the PWM pulses to modulate a voltage or current to be provided to an excitation electrode in the downhole logging tool. The digital excitation signal generator can also include a feedback module for maintaining a constant current output or constant voltage output to the excitation electrode.

### TECHNICAL FIELD

The present disclosure relates generally to devices for use in a wellbore in a subterranean formation. More specifically, but not by way of limitation, this disclosure relates to a digital excitation signal generator for a downhole logging tool.

### BACKGROUND

A well system (e.g., oil or gas wells for extracting fluids from a subterranean formation) can include various devices. For example, a well system can include a downhole logging tool (e.g., a measuring-while-drilling (“MWD”) tool, a logging-while-drilling (“LWD”) tool, or a wireline formation testing tool) for measuring or otherwise determining various properties of the subterranean formation from within a wellbore. The downhole logging tool can inject excitation signals (e.g., current signals or voltage signals) into the subterranean formation to determine properties of the formation. In some examples, the downhole logging tool may include a transmitter for injecting signals into the subterranean formation.

### BRIEF DESCRIPTION OF THE DRAWINGS

FIG. 1 is a schematic diagram of a well system in which a downhole logging tool can be deployed according to one example of the present disclosure.

FIG. 2 is a block diagram depicting an example of a downhole logging tool according to one example of the present disclosure.

FIGS. 3A-C are block diagrams depicting an example of a power amplifier of FIG. 2 that includes a digital excitation signal generator according to one example of the present disclosure.

FIG. 4 is a block diagram depicting an example of a proportional-integral-device controller of FIG. 3A according to one example of the present disclosure.

FIG. 5 is a flow chart depicting an example of a process for converting a digital waveform into pulses according to one example of the present disclosure.

FIG. 6 is a flow chart depicting an example of a process for modulating excitation signals to be injected into a wellbore formation according to one example of the present disclosure.

FIG. 7 is a graph depicting an example of a sine wave generated according to one example of the present disclosure.

FIG. 8 is a cross-sectional side view of another well system in which a downhole logging tool can be deployed according to one example of the present disclosure.

### DETAILED DESCRIPTION

Certain examples and features of the present disclosure are directed to a digital excitation signal generator for downhole logging tools.

A digital excitation signal generator can be used for configuring one or more transmitter devices of a downhole logging tool (e.g., a measuring-while-drilling (“MWD”) tool, a logging-while-drilling (“LWD”) tool, or a wireline formation testing tool). The downhole logging tool may inject excitation signals (e.g., current signals or voltage signals) into a subterranean formation via the transmitter devices. The digital excitation signal generator can be used to configure the excitation signals used by the transmitter devices.

For example, a downhole logging tool may generate excitation signals and inject the signals into a subterranean formation via a transmitter device of the downhole logging tool. The transmitter device can include a digital excitation signal generator. The digital excitation signal generator can include a processor, a pulse-width modulator (“PWM”) device, and an interface that are electrically coupled or otherwise communicatively coupled. The interface can be electrically coupled or otherwise communicatively coupled between an analog voltage or current source and an excitation electrode. The processor can generate and provide a digital waveform to the PWM device. In some examples, the processor can modify the digital waveform before providing the digital waveform to the PWM device. The PWM device can convert the digital waveform into PWM pulses. The PWM device can provide the pulses to the interface to activate transistors in the interface. The interface can use the PWM pulses to modulate a voltage or current to be provided to an excitation electrode from the analog voltage or current source.

In some examples, the digital excitation signal generator can also include a feedback module. The feedback module can maintain constant current output or constant voltage output to the excitation electrode.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative examples but, like the illustrative examples, should not be used to limit the present disclosure.

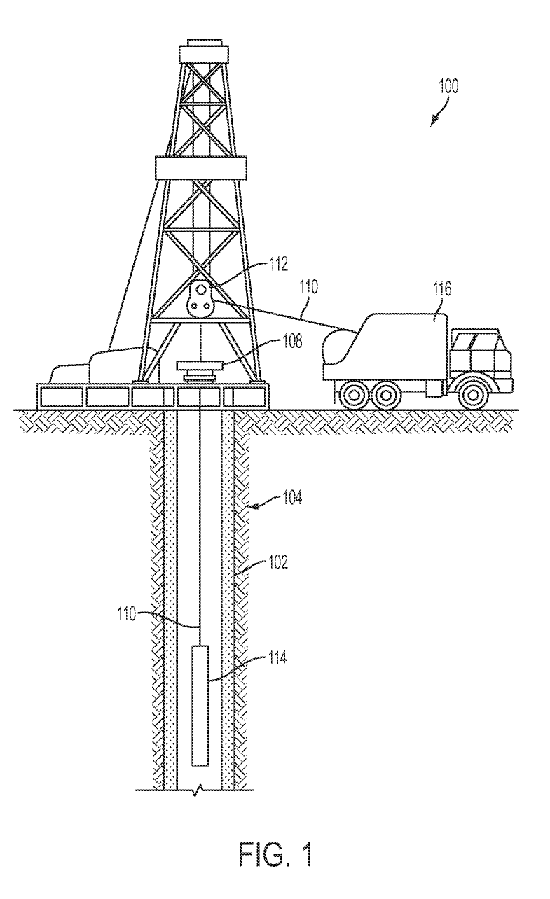

FIG. 1 is a schematic diagram of a well system 100 in which a downhole logging tool 114 can be deployed. The well system 100 includes a wellbore 102 extending through various earth strata. The wellbore 102 extends through subterranean formation 104.

The well system 100 can include at least one downhole logging tool 114 (e.g., an MWD tool, an LWD tool, or a wireline formation testing tool). The downhole logging tool 114 can be coupled to a wireline 110, slickline, or coiled tube that can be deployed into the wellbore 102 from the surface 108. The wireline 110, slickline, or coiled tube can be guided into the wellbore 102 using, for example, a guide 112 or winch. In some examples, the wireline 110, slickline, or coiled tube can be wound around a reel 116.

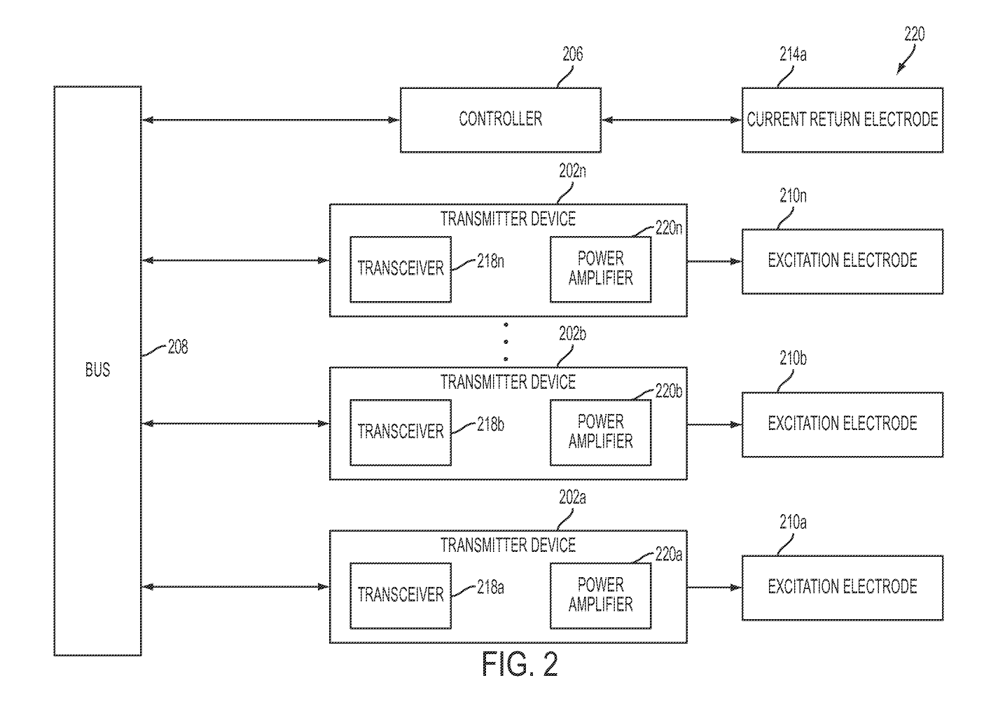

The downhole logging tool 114 can also include a transmitter for injecting signals into subterranean formation 104 for determining properties of the subterranean formation 104. For example, FIG. 2 is a block diagram depicting an example of a downhole logging tool 114.

The downhole logging tool 114 can include multiple transmitter devices 202a-n, a controller 206, a bus 208, and multiple excitation electrodes 210a-n. The transmitter devices 202a-n, the controller 206, the bus 208, and the excitation electrodes 210a-n can be positioned in a chassis.

The transmitter devices 202a-n can respectively include transceivers 218a-n and power amplifiers 220a-n. Each of the transmitter devices 202a-n can transmit electrical signals (e.g., an excitation current or voltage) into a downhole geological formation via the excitation electrodes 210a-n. The power amplifiers 220a-n can be used to modify the excitation current levels for electrical signals transmitted by the transmitter devices 202a-n. The magnitude of the excitation currents injected into the formation can be controlled by tuning or otherwise modifying the gains of the power amplifiers 220a-n for the transmitter devices 202a-n. The transceivers 218a-n can be used for communicating with the controller 206 via a controller area network (“CAN”) bus 208. In some examples, the downhole logging tool 114 can also include receiver devices. The receiver devices can detect electrical signals induced in the subterranean formation by the electrical signals and transmit digital data describing the voltage level or other attributes of received electrical signals. The receiver devices can be used to communicate with the controller 206 via the bus 208.

In a logging operation, the transmitter devices 202a-n can be respectively coupled to excitation electrodes 210a-n. The excitation electrodes 210a-n can be used to inject, drive, or otherwise provide excitation currents to the subterranean formation 104. Each of the transmitter devices 202a-n can transmit a respective electrical signal by injecting, driving, or otherwise providing a respective excitation current to the formation 104. The excitation currents can be returned from the formation 104 via a current return electrode 214a. The excitation currents can induce voltages in the formation. Receiver devices can detect, process, and calculate or otherwise determine voltages measured across a monitoring electrode.

The controller 206 can receive data from the transmitter devices 202a-n, process data from the transmitter devices 202a-n, and transmit the results of data processing to a control unit at a surface of a well system. A non-limiting example of a control unit is a computing device such as a desktop computer or other suitable computing device. The controller 206 can also configure the excitation current levels used by the transmitter devices 202a-n. The controller 206 can configure the transmitter devices 202a-n by digitally tuning the power amplifiers 220a-n. The controller 206 can digitally tune the power amplifiers 220a-n by communicating control signals via the CAN bus 208 or other suitable interface to the respective transceivers 218a-n of the transmitter devices 202a-n.

The controller 206 can communicate with the transmitter devices 202a-n via the CAN bus 208 or other suitable interface. The CAN bus 208 or other suitable interface can allow digital communication of data between the controller 206 and transmitter devices 202a-n.

The power amplifiers 220a-n for the transmitter devices 202a-n can include one or more devices suitable for modulating excitation signals to be injected into a wellbore formation. The power amplifiers 220a-n can be used to modify the excitation current or voltage levels for electrical signals transmitted by the transmitter devices 202a-n. The power amplifiers 220a-n can be switch mode power amplifiers. For example, the power amplifiers 220a-n can be a device for amplifying an analog signal that is converted to a set of pulses by a PWM device. The power amplifiers 220a-n can also provide a constant current output or a constant voltage output.

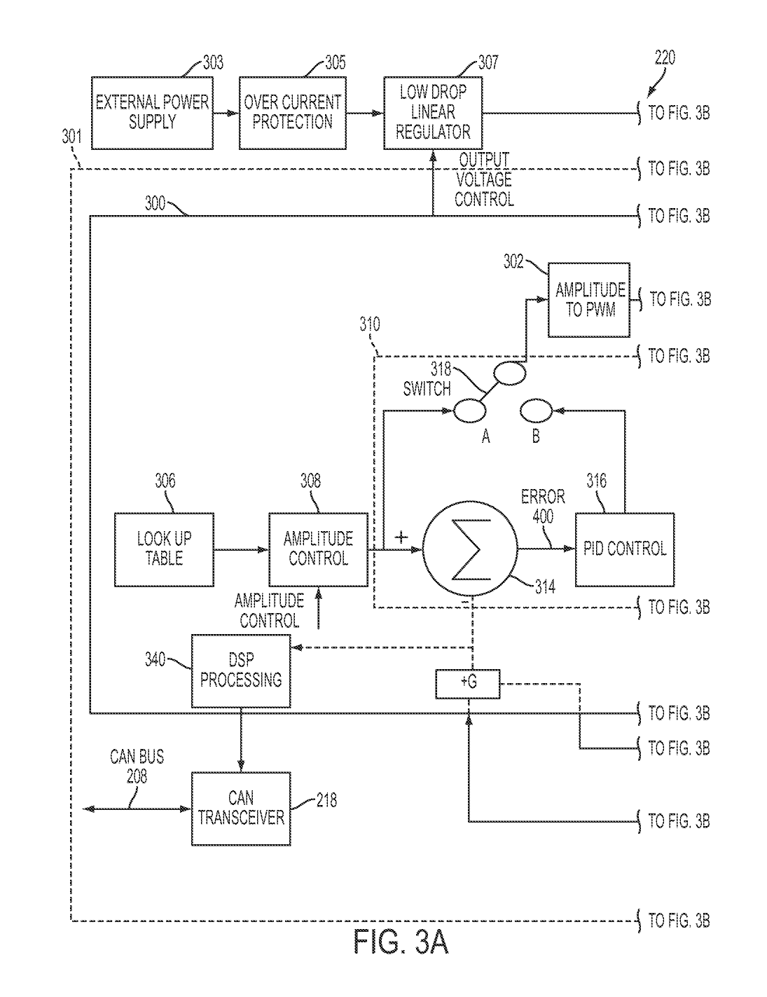

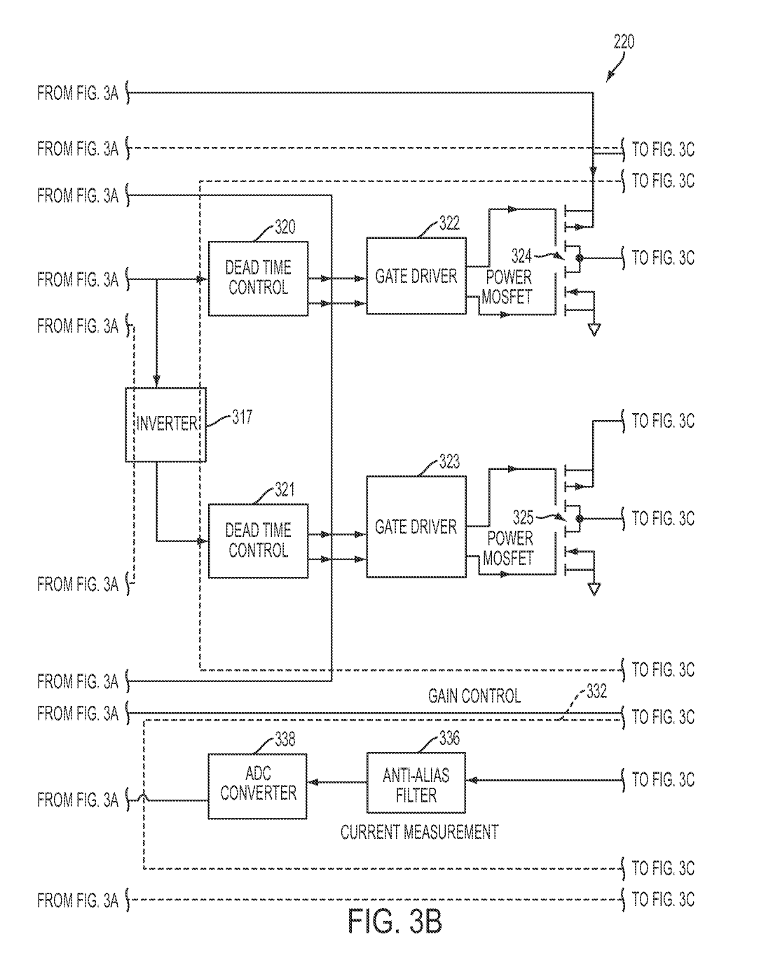

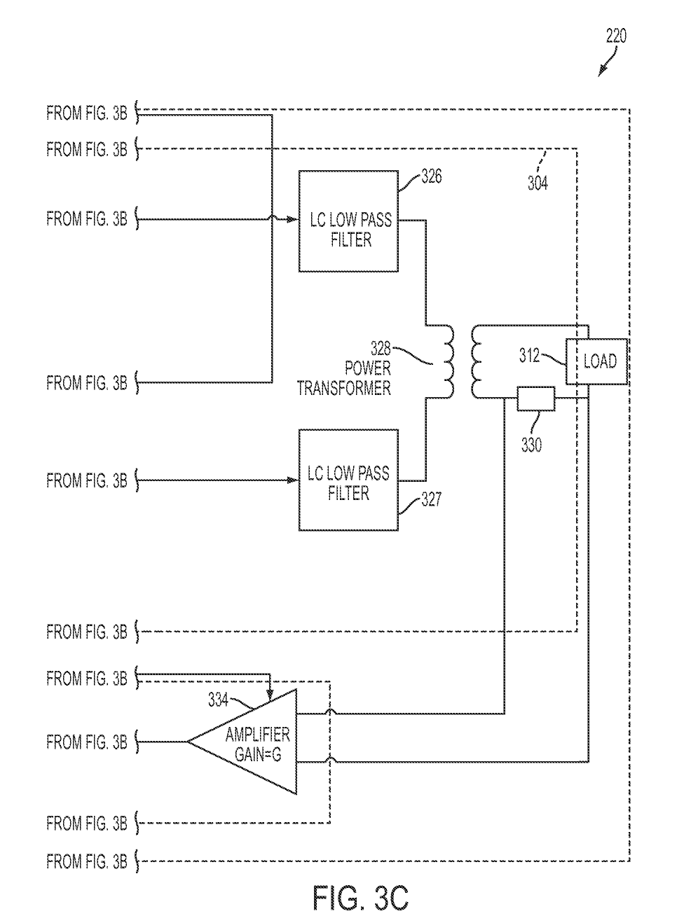

FIGS. 3A-C are block diagrams depicting an example of a power amplifier of 220 that includes a digital excitation signal generator 301.

In this example, the digital excitation signal generator 301 can include a processor 300, a PWM device 302, and an interface 304.

The processor 300 can include one processing device or multiple processing devices. A non-limiting example of the processor 300 includes a Field-Programmable Gate Array (“FPGA”). The processor 300 can generate a digital signal having a sinusoidal waveform. The processor 300 can be electrically coupled or otherwise communicatively coupled to the PWM device 302 and can provide the digital signal to the PWM device 302. The PWM device 302 can convert the digital signal into a pulse or a set of pulses. The width of each pulse generated by the PWM device 302 can correspond to the amplitude of the digital sinusoidal waveform at a given period of time. The PWM device can be electrically coupled or otherwise communicatively coupled to the interface 304. The interface 304 can include a device or group of devices that can be controlled by the widths of the pulses generated by the PWM device 302 for modulating a voltage or current provided to an excitation electrode from an analog voltage or current source, such as an external power supply 303.

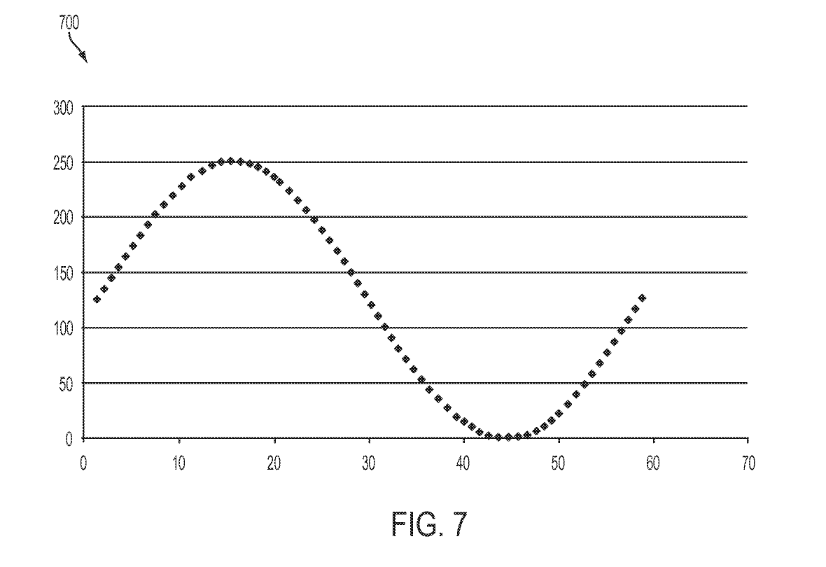

The processor 300 can provide the digital waveform to a PWM device 302. In some examples, the processor 300 may include or be communicatively coupled to a computer-readable medium. The computer-readable medium may store a look-up-table (“LUT”) 306. The LUT 306 may store values of a digital waveform. In some examples, the values stored in the LUT 306 may represent a pre-calculated waveform that is digitally generated. The LUT 306 may also contain signal amplitude information in relation to time for a given waveform. For example, the values stored in the LUT 306 may indicate that the sampling rate for a sine wave is f×N, where f is the frequency of the wave and N is a point value of the wave. Samples of the LUT 306 can be created using the formula:

$$Amplitude ( n ) = sin ( \frac{n \times 360}{f} ) \times Full Scale + Zero$$

where n is a sample number (0 to N-1), Full Scale has a value of 2(M-1)-1 where M is the bit resolution, and Zero has a value of 2(M-1)-1. A maximum value for the waveform using this formula is 2M-2 and the minimum value is 0. For example, FIG. 7 is a graph showing an example of a sine wave generated according to one example of the present disclosure. FIG. 7 is a graph 700 showing a 60 Hz sine wave with a 64-point and 8-bit resolution according to one example of the present disclosure.

The processor 300 or program code executed by the processor 300 can also include an amplitude control module 308. In some examples, the amplitude control module 308 can control the amplitude of a digital waveform provided by the processor 300 using the values stored in the LUT 306. For example, the amplitude control module 308 can modify the amplitude of the digital waveform generated by the processor 300 prior to the digital waveform being provided to the PWM device 302.

In some examples, the processor 300 can also include a feedback module 310. The feedback module 310 can be any hardware, software, or combination thereof that can be used for maintaining a constant current output to a load 312. The load 312 may be an excitation electrode for injecting excitation signals into a wellbore formation 104. The feedback module 310 may include a device or group of devices. For example, the feedback module 310 may include a summer module 314, a proportional-integral-derivative (“PID”) controller 316, and a switch 318.

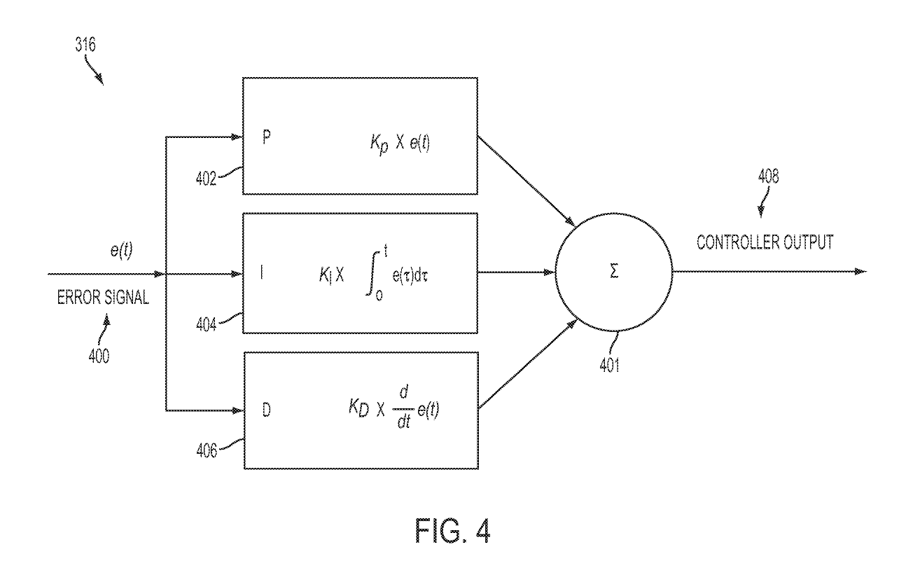

The summer module 314 may generate an error signal based on the output digital waveform received from the amplitude control module 308. In some examples, the error signal may represent a measured current value, provided by a current measurement module 332, and a specified value for the current. The measured current value can be a measured current from the wellbore formation. The summer module 314 may provide the error signal to the PID controller 316 to determine and output an error value. The error value can be used by the PID controller to modify the waveform provided to the PWM device 302 such that a constant current is provided to the load 312. An example of the operations performed by the PID controller is described herein with respect to FIG. 4.

The PWM device 302 can convert a digital waveform into a set of PWM pulses. The PWM device 302 can encode amplitudes of a digital waveform using PWM pulses. In some examples, the signal input into the PWM device 302 can be received from the output of the PID controller 316. In other examples, the signal input into the PWM device 302 can be received from the output of the amplitude control module 308.

In some examples, the PWM device 302 may include a timer. The PWM device 302 can use the timer to convert the received digital waveform into PWM pulses. The frequency of a PWM pulse can be equal to the sampling rate of the LUT 306. The width of the PWM pulse (e.g., duty cycle) can be proportional to the input amplitude data. The duration of the PWM pulse is 1/F_{S} where F_{S} is the sample rate as discussed above with respect to the generation of the digital waveform. The maximum amplitude value included in the LUT 306 can correspond to 100% of the duty cycle of the PWM pulse. The minimum amplitude value included in the LUT (e.g., 0) can correspond to 0% of the duty cycle of the PWM pulse.

The digital excitation signal generator 301 can also include an interface 304. The interface 304 can modulate a voltage or current provided to an excitation electrode from an analog voltage or current source such as the external power supply 303. The load 312 can be an excitation electrode for injecting excitation signals into a wellbore formation. In some examples, the external power supply 303 may be electrically coupled or otherwise communicatively coupled to an over-current protection security device 305. The over-current protection security device 305 may prevent excessive current flow. The over-current protection security device 305 may be electrically coupled or otherwise communicatively coupled to a low-drop linear regulator device 307. The low-drop linear regulator device 307 may improve a power supply rejection ratio.

In some examples, the interface 304 can be controllable by widths of a set of pulses for modulating a voltage or current provided to the excitation electrode from the power supply 303 or another analog voltage or current source. The interface 304 may include a device or multiple devices for modulating the voltage or current provided to an excitation electrode using widths of PWM pulses. For example, the interface 304 may include an inverter 317 electrically coupled or otherwise communicatively coupled to dead-time control devices 320, 321. The dead-time control devices 320, 321 may be used to avoid shoot through current that may occur if a first transistor 324 and a second transistor 325 are partially in an ON state. Shoot through current can be a rush of current that occurs if both the transistors 324, 325 are partially in an ON state. The dead-time control devices 320, 321 may also be used to reduce the amount of dead time. The dead time can be a period during a switching transition in which both the upper transistor and the lower transistor are driven into a cut-off mode and are partially in an ON state. In some examples, the dead-time control devices 320, 321 may be controlled remotely by the controller 206. For example, the controller 206 can configure the dead-time control devices 320, 321 to avoid long dead times, which may reduce efficiency of the power amplifier 220. The interface 304 may also include gate driver devices 322, 323. The gate driver devices 322, 323 may include any devices suitable for driving the gate of a transistor or other suitable transistor by amplifying logic level signals from the processor 300.

As discussed above, the interface 304 may also include the transistors 324, 325. Although FIG. 3B depicts the transistors 324, 325 as MOSFETs for illustrative purposes, any suitable transistors or other switching components can be used. In some examples, the transistors 324, 325 may be set to either be in an ON or OFF state. Setting the transistors 324, 325 to either be in an ON or OFF state may increase the efficiency of the power amplifier 220.

The interface 304 may also include low-pass filters 326, 327. Each of the low-pass filters 326, 327 can be a filter that passes signals with a frequency lower than a cutoff frequency and attenuates signals with frequencies higher than the cutoff frequency. In some examples, the low-pass filters 326, 327 may remove high frequency switching noise at the output of the circuitry.

The interface 304 may also include a power transformer 328. The power transformer 328 can be used to isolate the load 312. The power transformer 328 can be used to increase an output current or voltage to be provided to the load 312.

The interface 304 may also include a current sampling resistor 330. The current sampling resistor 330 may be electrically coupled to the load 312. In some examples, the current sampling resistor 330 may sample the output current and provide the sampled output current to a current measurement module 332.

The current measurement module 332 of the digital excitation signal generator 301 can include an amplifier device 334, an anti-alias filter 336, and an analog-to-digital converter (“ADC”) 338 that are electrically coupled to one another. In some examples, the processor 300 may configure the amplifier device 334 to modify an output current. For example, the amplifier device 334 may be configured by the processor 300 to increase a gain of a sampled output current based on the sampled current being too low for measurement purposes. The ADC 338 can be any device for converting an analog signal (e.g., amplified, filtered version of the sampled current) to a digital signal that can be used by the processor 300. In some examples, the ADC 338 can be a zero-latency analog-to-digital converter. For example, the ADC 338 can be a successive approximation analog-to-digital converter.

The processor 300 may also include a digital signal processor (“DSP”) module 340. The DSP module 340 can be any processor for measuring, filtering or compressing a signal. In some examples, the DSP module 340 may process the current and determine the amplitude of the output current. The DSP module 340 may provide this data to the CAN transceiver 218 and the data may be transmitted to a surface of a wellbore via a CAN bus 208.

FIG. 4 is a block diagram depicting an example of a PID controller 316. The PID controller 316 may include a control loop feedback device or program code executed by a control loop feedback device. The PID controller 316 may involve three separate constant-parameters: a proportional value, an integral value and a derivative value. The proportional value depends on present error. The integral value depends on accumulated past error. The derivative value is a prediction of future error based on a current rate of change. For example, in FIG. 4, a proportional value 402, an integral value 404, and a derivative value 406 are denoted P, I, and D respectively. The PID controller 316 may also include a summer module 401. In the example depicted in FIG. 4, the output of the summer module 401 is the sum of the proportional value 402, then integral value 404, and the derivative value 406.

The PID controller 316 may determine and output an error value. The error value may represent the difference between the measured current value and a specified value for the current provided to a load (e.g., the load 312 in FIG. 3C). For example, the feedback module 310 in FIG. 3C can be electrically coupled or otherwise communicatively coupled to the current measurement module 332. The current measurement module 332 may provide data to the summer module 314. The data may represent a measured current value. The summer module 314 may provide an error signal 400 to the PID controller. The error signal 400 may represent the measured current value, provided by the current measurement module 332, and a specified value for the output current. The PID controller 316 can use the error signal 400 to determine an error value. The PID controller may compare the measured current value to the specified value of the output current to determine an error value. The error value may be modified by the proportional value 402, the integral value 404, or the derivative value 406, or any combination thereof. The summer module 401 may combine the error values as modified by the proportional value 402, the integral value 404, or the derivative value 406. The sum of the error values may be provided to the controller output 408 for adjusting the output current such that a subsequently measured current value corresponds to the specified value.

The feedback module 310 can also include a switch 318. The switch 318 may be any switching component suitable for selectively coupling the feedback module 310 to the PWM device 302 for maintaining a constant current output. In some examples, the switch 318 may couple the PWM device 302 to a path that includes the amplitude control module 308 and that does not include the PID controller 316. Coupling the PWM device 302 to a path to the amplitude control module 308 without using the PID controller 316 can configure the power amplifier 220 to provide a constant voltage output to the load 312. In other examples, the switch 318 may configure the power amplifier 220 to provide a constant current output to the load 312. For example, for the power amplifier 220 depicted in FIGS. 3A-C, if the switch 318 is set to position “A”, the feedback module 310 loop is broken and the power amplifier 220 maintains a constant voltage output to the load 312. If the switch 318 is set to position “B”, the feedback module loop is complete and the power amplifier 220 maintains a constant current output to the load 312. In some examples, the controller 206 can configure the switch 318 for maintaining a constant current or voltage output. The controller 206 can control the switch 318 by communicating control signals to the transmitter devices 202a-n, depicted in FIG. 2, via the CAN bus 208 or other suitable interface.

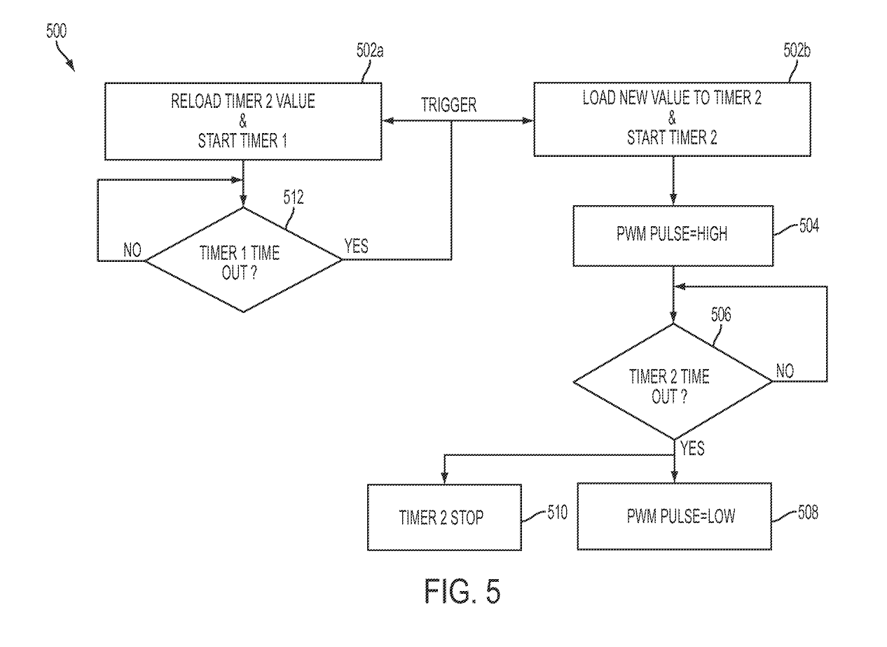

In some examples, the PWM device 302 may translate amplitude into PWM pulses according to a process for converting amplitude into PWM pulses. For example, FIG. 5 is a flow chart depicting an example of a process for converting a digital waveform into pulses.

In blocks 502a and 502b, a first timer and a second timer are started. In some examples, a controller (e.g., the controller 206 depicted in FIG. 2) can start the first timer and the second timer. The controller can load a first value for the first timer and a second value for the second timer prior to starting the first timer and the second timer. The value for the first timer can be equal to the duration of the PWM pulse. The value for the second timer can be equal to the width of the PWM pulse. The controller can load and start the first timer and the second timer by digitally tuning power amplifiers (e.g., the power amplifiers 220a-n depicted in FIG. 2) of transmitter devices (e.g., the transmitter devices 202a-n depicted in FIG. 2). In some examples, the controller can load and start the first timer and the second timer by communicating control signals to the transmitter devices via a CAN bus (e.g., the CAN bus 208 depicted in FIG. 2) or other suitable interface.

In block 504, the PWM pulse is set to a high level. In some examples, the controller can set the PWM pulse to the high level. The controller can set the PWM pulse to the high level by digitally tuning the power amplifiers of the transmitter devices. In some examples, the controller can set the PWM pulse to high by communicating control signals to the transmitter devices via the CAN bus or other suitable interface.

In block 506, the value of the second timer is measured. In some examples, the controller can measure the value of the second timer. The controller can measure the value of the second timer by receiving data from the transmitter devices via the CAN bus or other suitable interface.

In block 508, the PWM pulse is set to a low level. The controller can set the PWM pulse to the low level based on from the data received from the transmitter devices that the value of the second timer has reached zero. If the controller determines that the value of the second timer is greater than zero, the controller can measure the value of the second timer at a subsequent time to determine if the second timer value has reached zero. The controller can determine that the value of the second timer has reached zero by processing data received from the transmitter devices. The controller can set the PWM pulse to the low level by digitally tuning the power amplifiers of the transmitter devices. In some examples, the controller can set the PWM pulse to low by communicating control signals to the transmitter devices via the CAN bus or other suitable interface.

In block 510, the second timer may be stopped. In some examples, the controller can stop the second timer after the controller determines that the value of the second timer has reached zero and the PWM pulse is set to the low level. The controller can stop the second timer by digitally tuning the power amplifiers of the transmitter devices. In some examples, the controller can stop the second timer by communicating control signals to the transmitter devices via the CAN bus or other suitable interface.

In block 512, the value of the first timer is measured. In some examples, the controller can measure the value of the first timer. The controller can measure the value of the first timer in substantially the same manner as the controller measures the value of the second timer, as discussed above. The controller can also determine, based on data received from the transmitter devices, that the value of the first timer has reached zero. If the controller determines that the value of the first timer has reached zero, the controller can return to blocks 502a, 502b and re-load and re-start the first timer and the second timer. If the controller determines that the value of the first timer is greater than zero, the controller can measure the value of the first timer at a subsequent time to determine if the value of the first timer has reached zero.

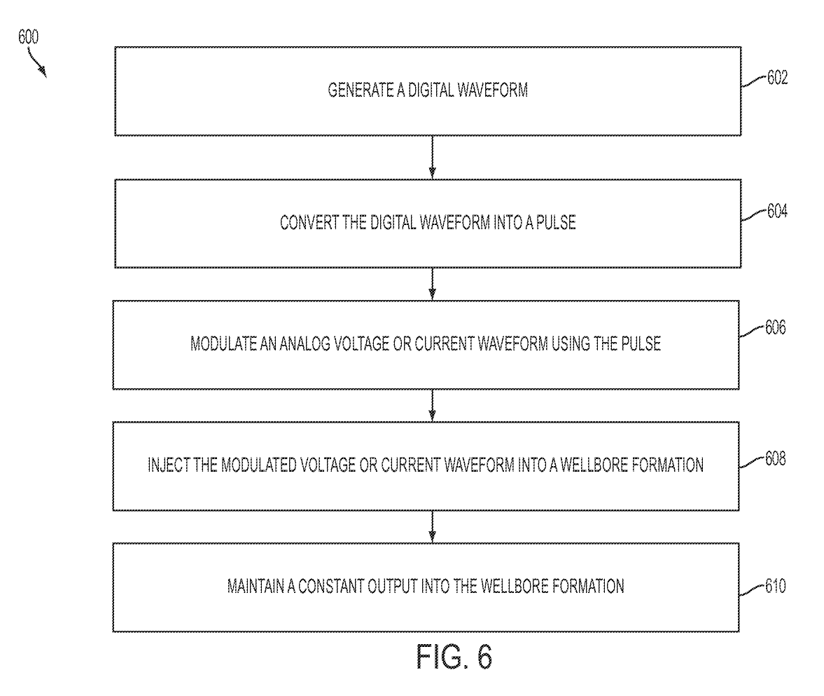

FIG. 6 is a flow chart depicting an example of a process 600 for modulating excitation signals to be injected into a wellbore formation.

In block 602, a digital waveform is generated. In some examples, a power amplifier (e.g., the power amplifier 220) including a processor (e.g., the processor 300) can generate the digital waveform. The processor can provide the digital waveform to a PWM device (e.g., the PWM device 302). In some examples, the processor may be communicatively coupled to a computer-readable medium. The computer-readable medium may store a LUT (e.g., the LUT 306) having values of the digital waveform. The values of the digital waveform may represent a pre-calculated waveform created digitally. The LUT may also contain signal amplitude information in relation to time for a given digital waveform. In some examples, the processor may generate the digital waveform and provide the digital waveform to a PWM device.

In block 604, the digital waveform is converted into a set of pulses. For example, the PWM device in the power amplifier may convert the digital waveform into a set of PWM pulses. The PWM device may also convert the digital waveform into a set of pulses by converting the amplitudes of the digital waveform into pulses. The width of each pulse may correspond to the amplitude of the digital waveform at a given period of time. In some examples, an amplitude control module (e.g., the amplitude control module 308) may modify the amplitude of the digital waveform prior to the digital waveform being provided to the PWM device to be converted into a pulse, as described above with respect to FIG. 2. The PWM device may also use a timer for converting the digital waveform into a pulse.

In block 606, an analog voltage or current waveform is modulated using the set of pulses. In some examples, an interface included in the power amplifier (e.g., the interface 304) may modulate the analog voltage or current waveform using the set of pulse. For example, an external power source or analog voltage or current source (e.g., the external power supply 303) may provide an analog voltage or current waveform. The interface may include a group of devices electrically coupled to the PWM device for modulating the analog voltage or current using widths of pulses outputted by the PWM device. In some examples, the pulses outputted by the PWM device can be used to selectively activate transistors in the interface, as described above with respect to FIG. 2. Selectively activating transistors in the interface using pulses outputted from the PWM device can modulate the analog voltage or current waveform to correspond to the digital waveform generated by the processor.

In block 608, the modulated voltage or current waveform is injected into a wellbore formation (e.g., subterranean formation 104). For example, the power amplifier may be included in a transmitter device (e.g., the transmitter device 202a) in a downhole logging tool (e.g., the downhole logging tool 114). The transmitter device can inject an excitation signal into a wellbore formation. The transmitter device may be electrically coupled to an excitation electrode (e.g., the excitation electrode 210a) that can inject the modulated voltage or current waveform into the wellbore formation. The excitation electrode can be used to inject, drive, or otherwise provide the modulated voltage or current to the formation.

In block 610, constant output into the wellbore formation is maintained. For example, the power amplifier may include a feedback module (e.g., the feedback module 310) for maintaining a constant output to the excitation electrode, as described above with respect to FIG. 2. The feedback module may be used to maintain a constant current output to the excitation electrode. The feedback module may include a device or a group of devices for maintaining a constant output to the excitation electrode. For example, the feedback module may include a summer module (e.g., the summer module 314), a PID controller (e.g., the PID controller 316) and a switch (e.g., the switch 318) for maintaining a constant current output to the excitation electrode. The switch can selectively couple the feedback module to a PWM device for maintaining a constant current output to the excitation electrode. In other examples, the switch can decouple the feedback module and the PWM device for maintaining a constant voltage output. In some examples, block 610 may be omitted from the process 600.

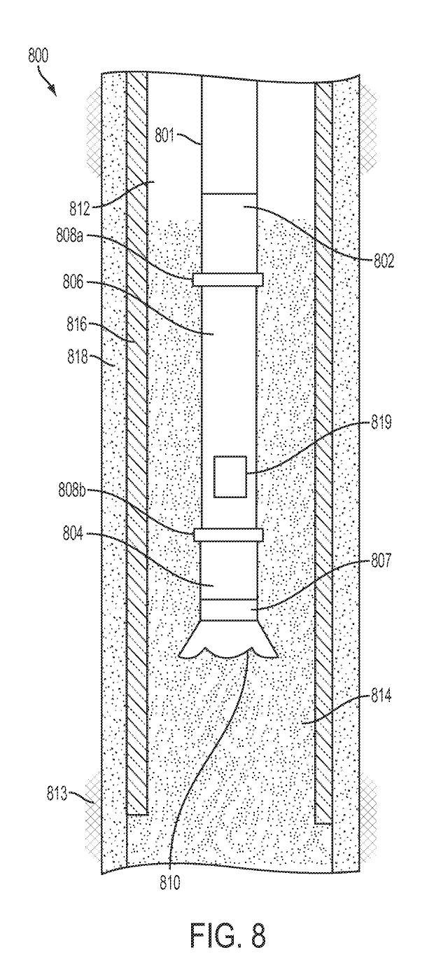

One or more features and examples described above can be implemented in a well system that includes measuring-while-drilling tools. For example, FIG. 8 is a cross-sectional side view of a well system 800 in which a downhole logging tool can be deployed according to one example of the present disclosure. In this example, the well system 800 includes a wellbore. A casing string 816 and a cement sheath 818 can be positioned in the wellbore. In some examples, the cement sheath 818 can couple the casing string 816 to a wall of the wellbore. In some examples, the wellbore can include fluid 814. An example of the fluid 814 can include mud. The fluid 814 can flow in an annulus 812 positioned between a well tool 801 and a wall of the casing string 816.

The well tool 801 can be positioned in the wellbore. In some examples, the well tool 801 is a measuring-while-drilling tool. For example, the well tool 801 can include a logging-while-drilling tool, a pressure-while-drilling tool, a temperature-while-drilling tool, or any combination of these. The well tool 801 can include various subsystems 802, 804, 806, 807. For example, the well tool 801 can include a subsystem 802 that includes a communication subsystem. The well tool 801 can also include a subsystem 804 that includes a saver subsystem or a rotary steerable system. A tubular section or an intermediate subsystem 806 (e.g., a mud motor or measuring-while-drilling module) can be positioned between the subsystems 802, 804. The well tool 801 can include a drill bit 810 for drilling the wellbore. The drill bit 810 can be coupled to another tubular section or intermediate subsystem 807 (e.g., a measuring-while-drilling module or a rotary steerable system).

In some examples, the well tool 801 can include tubular joints 808a, 808b. Tubular joints 808a, 808b can allow the well tool 801 to bend or can couple various well tool subsystems 802, 804, 806, 807 together. The well tool 801 can also include a transmitter 819 for injecting signals into subterranean formation 813 for determining properties of the subterranean formation 813. In some examples, the well tool 801 or the transmitter 810 can include components configured in substantially the same manner as described with respect to FIGS. 3A-C and FIG. 4.

Various types of digital excitation signal generators can be used to modulate excitation current or voltage to be injected into a subterranean formation by a downhole logging tool. The following are examples:

### EXAMPLE 1

A control device that is positionable in a wellbore can include a memory device. The memory device can store instructions executable by a processor. The processor can be communicatively coupled to the memory device. The processor can execute the instructions stored on the memory device to generate a digital waveform. The control device can also include a pulse-width modulator device. The pulse-width modulator device can be communicatively coupled to the processor. The pulse-width modulator device can convert the digital waveform into a plurality of pulses. The control device can also include an interface. The interface can be coupled to the pulse-width modulator device. The interface can also be couplable between an analog voltage or current source and an excitation electrode. The interface can be controllable by widths of the plurality of pulses to modulate a voltage or a current provided to the excitation electrode from the analog voltage or current source.

### EXAMPLE 2

The control device of Example 1 may feature the memory device storing a look-up-table. The look-up-table can have values of the digital waveform. The processor can further include an amplitude control module. The amplitude control module can modify the amplitude of the digital waveform provided to the pulse-width modulator device.

### EXAMPLE 3

The control device of any of Examples 1-2 may feature the processor including a feedback module. The feedback module can be selectively couplable to a signal path to the pulse-width modulator device. The feedback module can maintain a constant current output to the excitation electrode.

### EXAMPLE 4

The control device of any of Examples 1-3 may feature the feedback module including a summer module. The summer module can generate an error signal using an output digital waveform received from the amplitude control module. The feedback module can also include a proportional-integral-derivative controller. The proportional-integral-derivative controller can be coupled to the summer module and can determine an error value based on the error signal. The feedback module can also include a switch. The switch can selectively couple the proportional-integral-derivative controller to the pulse-width modulator device. The control device may also feature the processor being configured for modifying an amplitude of the digital waveform such that a constant current output is provided to the excitation electrode.

### EXAMPLE 5

The control device of Example 4 may feature the proportional-integral-derivative controller determining the error value based on a measured current value from a current measurement module and a specified value for the current.

### EXAMPLE 6

The control device of any of Examples 4-5 may feature the proportional-integral-derivative controller determining the error value based on parameters. The parameters can include a proportional value. The proportional value can be based on a present error value. The parameters can also include an integral value. The integral value can be based on an accumulated past error value. The parameters can also include a derivative value. The derivative value can be based on a future error value and a current rate of change. The proportional-integral-derivative controller can also include another summer module. The proportional-integral-derivative controller can also include a controller output. The proportional-integral-derivative controller can use the values of each parameter for modifying the measured current value and the specified value for the current and providing a modified value from each parameter to the other summer module. The other summer module can combine the modified value from each parameter to provide an error value to the controller output. The controller output can output the error value.

### EXAMPLE 7

The control device of Example 4 may feature the switch selectively decoupling the proportional-integral-derivative controller from the pulse-width modulator device for maintaining a constant voltage output to the excitation electrode.

### EXAMPLE 8

The control device of any of Examples 1-7 may feature the interface including at least one transistor. The transistor can be controllable by the widths of the plurality of pulses. The interface can also include a dead time control device. The dead time control device can reduce the amount of time during which the at least one transistor is partially in an ON state. The dead time control device can also control the current provided to the excitation electrode from the transistor. The interface can also include a gate driver device. The gate driver device can drive the gate of the at least one transistor. The gate driver device can be coupled to the dead time control device. The gate driver device can also be coupled to the at least one transistor.

### EXAMPLE 9

A downhole logging tool can include an analog voltage or current source. The analog voltage or current source can be electrically coupled to an excitation electrode. The downhole logging tool can also include a control device. The control device can include a processor. The processor can generate a digital waveform. The control device can also include a pulse-width modulator device. The pulse-width modulator device can be communicatively coupled to the processor. The pulse-width modulator device can convert the digital waveform into a plurality of pulses. The control device can also include an interface. The interface can be coupled between the analog voltage or current source and the excitation electrode. The interface can be controllable by widths of the plurality of pulses to modulate a voltage or a current provided to the excitation electrode from the analog voltage or current source.

### EXAMPLE 10

The downhole logging tool of Example 9 may feature the processor further including a feedback module. The feedback module can be selectively couplable to a signal path to the pulse-width modulator device. The feedback module can maintain a constant current output to the excitation electrode.

### EXAMPLE 11

The downhole logging tool of any of Examples 9-10 may feature the interface including at least one transistor. The transistor can be controllable by the widths of the plurality of pulses. The interface can also include a dead time control device. The dead time control device can reduce the amount of time during which the at least one transistor is partially in an ON state. The dead time control device can also control the current provided to the excitation electrode from the transistor. The interface can also include a gate driver device. The gate driver device can drive the gate of the at least one transistor. The gate driver device can be coupled to the dead time control device. The gate driver device can be coupled to the at least one transistor.

### EXAMPLE 12

A method can include providing, by an analog voltage or current source, an analog voltage or current waveform. The method can also include generating, by a processor, a digital waveform. The method can also include converting, by a pulse-width modulator device, the digital waveform into a plurality of pulses. The method can also include modulating, by an interface, the analog voltage or current waveform using the widths of the plurality of pulses. The modulated analog voltage or current waveform can be injected into a wellbore formation via an excitation electrode.

### EXAMPLE 13

The method of Example 12 may feature the digital waveform being generated from a look-up-table. The look-up-table can have values of the digital waveform.

### EXAMPLE 14

The method of any of Examples 12-13 may feature converting the digital waveform into the plurality of pulses by modifying, by the processor, an amplitude of the digital waveform and providing the digital waveform to the pulse-width modulator device. The method may also feature converting the digital waveform into the plurality of pulses by converting, by the pulse-width modulator device, the digital waveform into the plurality of pulses.

### EXAMPLE 15

The method of any of Examples 12-14 may feature maintaining a constant current output to the excitation electrode based on a current measurement from the wellbore formation.

### EXAMPLE 16

The method of Example 15 may feature maintaining a constant current output by measuring, by a current measurement module, the current waveform to determine a measured current value. The method may also feature maintaining a constant current output by generating, by a proportional-integral-derivative controller, an error value based on the measured current value and a specified value for the current. The method may also feature maintaining a constant current output by coupling the proportional-integral-derivative controller to the pulse-width modulator device.

### EXAMPLE 17

The method of Example 16 may feature generating the error value by comparing the measured current value to the specified value for the current.

### EXAMPLE 18

The methods of any of Examples 12-17 may feature modulating the analog voltage or current waveform by activating, using the plurality of pulses, a transistor coupled between the analog voltage or current source and the excitation electrode, such that the modulated analog voltage or current waveform corresponds to the digital waveform. The method may also feature outputting a modulated voltage or current waveform by the transistor.

### EXAMPLE 19

The method of Example 18 may feature filtering the modulated voltage or current waveform outputted by the transistor prior to the modulated voltage or current waveform being provided to the excitation electrode.

### EXAMPLE 20

The method of Example 19 may feature controlling, by a dead-time control device, the modulated voltage or current waveform prior to the modulated voltage or current waveform being provided to a gate driver. The gate driver can be coupled between the dead-time control device and the transistor. The method may also feature amplifying, by the gate driver device, the modulated voltage or current provided to the transistor.

The foregoing description of certain examples, including illustrated examples, has been presented only for the purpose of illustration and description and is not intended to be exhaustive or to limit the disclosure to the precise forms disclosed. Numerous modifications, adaptations, and uses thereof will be apparent to those skilled in the art without departing from the scope of the disclosure.

1. A control device that is positionable in a wellbore, the control device comprising:
a memory device in which instructions executable by a processor are stored;
the processor communicatively coupled to the memory device and operable for executing the instructions to generate a digital waveform;
a pulse-width modulator device communicatively coupled to the processor and operable for converting the digital waveform into a plurality of pulses; and
an interface coupled to the pulse-width modulator device and couplable between an analog voltage or current source and an excitation electrode, wherein the interface is controllable by widths of the plurality of pulses to modulate a voltage or a current provided to the excitation electrode from the analog voltage or current source.

2. The control device of claim 1, wherein the memory device stores a look-up-table having values of the digital waveform and the processor further comprises an amplitude control module operable for modifying the amplitude of the digital waveform provided to the pulse-width modulator device.

3. The control device of claim 1, wherein the processor further comprises a feedback module selectively couplable to a signal path to the pulse-width modulator device, the feedback module operable for maintaining a constant current output to the excitation electrode.

4. The control device of claim 3, wherein the feedback module comprises:
a summer module operable for generating an error signal using an output digital waveform received from the amplitude control module;
a proportional-integral-derivative controller coupled to the summer module operable for determining an error value based on the error signal; and
a switch operable for selectively coupling the proportional-integral-derivative controller to the pulse-width modulator device, wherein the processor is configured for modifying an amplitude of the digital waveform such that a constant current output is provided to the excitation electrode.

5. The control device of claim 4, wherein the proportional-integral-derivative controller is operable for determining the error value based on a measured current value from a current measurement module and a specified value for the current.

6. The control device of claim 4, wherein the proportional-integral-derivative controller is operable for determining the error value based on parameters comprising:
a proportional value based on a present error value;
an integral value based on an accumulated past error value; and
a derivative value based on a future error value and a current rate of change;
wherein the proportional-integral-derivative controller further comprises an additional summer module and a controller output, wherein the proportional-integral-derivative controller is operable for using the values of each parameter for modifying the measured current value and the specified value for the current and providing a modified value from each parameter to the summer module, wherein the additional summer module is operable for combining the modified value from each parameter to provide an error value to the controller output, wherein the controller output is operable for outputting the error value.

7. The control device of claim 4, wherein the switch is operable to selectively decouple the proportional-integral-derivative controller from the pulse-width modulator device for maintaining a constant voltage output to the excitation electrode.

8. The control device of claim 1, wherein the interface includes:
at least one transistor controllable by the widths of the plurality of pulses;
a dead time control device operable for reducing the amount of time during which the at least one transistor is partially in an ON state and operable for controlling the current provided to the excitation electrode from the transistor; and
a gate driver device operable for driving the gate of the at least one transistor, the dead time control device being coupled to the gate driver device and the gate driver device being coupled to the at least one transistor.

9. A downhole logging tool comprising:
an analog voltage or current source electrically coupled to an excitation electrode; and
a control device comprising:
a processor operable for generating a digital waveform;
a pulse-width modulator device communicatively coupled to the processor and operable for converting the digital waveform into a plurality of pulses; and
an interface coupled between the analog voltage or current source and the excitation electrode, wherein the interface is controllable by widths of the plurality of pulses to modulate a voltage or a current provided to the excitation electrode from the analog voltage or current source.

10. The downhole logging tool of claim 9, wherein the processor further comprises a feedback module selectively couplable to a signal path to the pulse-width modulator device, the feedback module operable for maintaining a constant current output to the excitation electrode.

11. The downhole logging tool of claim 9, wherein the interface includes:
at least one transistor controllable by the widths of the plurality of pulses;
a dead time control device operable for reducing the amount of time during which the at least one transistor is partially in an ON state and operable for controlling the current provided to the excitation electrode from the transistor; and
a gate driver device operable for driving the gate of the at least one transistor, the dead time control device being coupled to the gate driver device and the gate driver device being coupled to the at least one transistor.

12. A method comprising:
providing, by an analog voltage or current source, an analog voltage or current waveform;
generating, by a processor, a digital waveform;
converting, by a pulse-width modulator device, the digital waveform into a plurality of pulses; and
modulating, by an interface, the analog voltage or current waveform using the widths of the plurality of pulses, wherein the modulated analog voltage or current waveform is injected into a wellbore formation via an excitation electrode.

13. The method of claim 12, wherein the digital waveform is generated from a look-up-table having values of the digital waveform.

14. The method of claim 12, wherein converting the digital waveform into the plurality of pulses comprises:
modifying, by the processor, an amplitude of the digital waveform and providing the digital waveform to the pulse-width modulator device; and
converting, by the pulse-width modulator device, the digital waveform into the plurality of pulses.

15. The method of claim 12, further comprising maintaining a constant current output to the excitation electrode based on a current measurement from the wellbore formation.

16. The method of claim 15, wherein maintaining a constant current output comprises:
measuring, by a current measurement module, the current waveform to determine a measured current value;
generating, by a proportional-integral-derivative controller, an error value based on the measured current value and a specified value for the current; and
coupling the proportional-integral-derivative controller to the pulse-width modulator device.

17. The method of claim 16, wherein generating the error value includes comparing the measured current value to the specified value for the current.

18. The method of claim 12, wherein modulating the analog voltage or current waveform includes:
activating, using the plurality of pulses, a transistor coupled between the analog voltage or current source and the excitation electrode, such that the modulated analog voltage or current waveform corresponds to the digital waveform; and
outputting a modulated voltage or current waveform by the transistor.

19. The method of claim 18, further comprising filtering the modulated voltage or current waveform outputted by the transistor prior to the modulated voltage or current waveform being provided to the excitation electrode.

20. The method of claim 19, further comprising:
controlling, by a dead-time control device, the modulated voltage or current waveform prior to the modulated voltage or current waveform being provided to a gate driver coupled between the dead-time control device and the transistor; and
amplifying, by the gate driver device, the modulated voltage or current provided to the transistor.
